(19) United States
(12) Patent Application Publication
(10) Pub. No.: US 2020/0071566 A1
(43) Pub. Date: Mar. 5, 2020

(54) SLURRY COMPOSITION FOR CHEMICAL MECHANICAL POLISHING

(71) Applicant: Samsung Electronics Co., Ltd., Suwon-si (KR)

(72) Inventors: Sang-hyun Park, Hwaseong-si (KR); Hyo-san Lee, Hwaseong-si (KR); Won-ki Hur, Suwon-si (KR); Jung-yoon Kim, Pyeongtaek-si (KR); Jun-ha Hwang, Pyeongtaek-si (KR); Chang-gil Kwon, Anseong-si (KR); Sung-pyo Lee, Anseong-si (KR)

(73) Assignee: KCTECH CO., LTD., Anseong-si (KR)

(21) Appl. No.: 16/553,623

(22) Filed: Aug. 28, 2019

(30) Foreign Application Priority Data
Aug. 30, 2018 (KR) 10-2018-0103031

(51) Int. Cl. C09G 1/02

(52) U.S. Cl. CPC C09G 1/02

(57) ABSTRACT

A slurry composition for a chemical mechanical polishing (CMP) process includes about 0.1% by weight to about 10% by weight of polishing particles, about 0.001% by weight to about 1% by weight of an amine compound, about 0.001% by weight to about 1% by weight of a first cationic compound that is amino acid, about 0.001% by weight to about 1% by weight of a second cationic compound that is organic acid, and about 1% by weight to about 5% by weight of polyhydric alcohol including at least two hydroxyl groups.

### CROSS-REFERENCE TO RELATED APPLICATION

This application claims the benefit of priority under 35 U.S.C. § 119 to Korean Patent Application No. 10-2018-0103031, filed on Aug. 30, 2018, in the Korean Intellectual Property Office, the disclosure of which is incorporated herein in its entirety by reference.

### BACKGROUND

The disclosure relates to a slurry composition for a chemical mechanical polishing (CMP) process, and more particularly, to a slurry composition for a CMP process, which may have improved polishing selectivity with respect to silicon nitride-silicon oxide without sacrificing a polishing rate and while effectively inhibiting a dishing phenomenon.

In a semiconductor device manufacturing process, a CMP process is widely being used as a planarization technique for removing a step difference between films formed on a substrate. The films formed on the substrate may be planarized by interposing a slurry composition including polishing particles between the substrate and a polishing pad. However, it is important to improve the slurry composition in terms of a polishing rate, a polishing selectivity, and inhibition of dishing.

### SUMMARY

The disclosed embodiments provide a slurry composition for a chemical mechanical polishing (CMP) process, which may have an improved polishing selectivity with respect to silicon nitride-silicon oxide without sacrificing a polishing rate and effectively inhibit a dishing phenomenon.

According to some aspects, the disclosure is directed to a slurry composition for a chemical mechanical polishing (CMP) process, the slurry composition comprising: about 0.1% by weight to about 10% by weight of polishing particles; about 0.001% by weight to about 1% by weight of an amine compound; about 0.001% by weight to about 1% by weight of a first cationic compound that is amino acid; about 0.001% by weight to about 1% by weight of a second cationic compound that is organic acid; and about 1% by weight to about 5% by weight of non-ionic polyhydric alcohol including at least two hydroxyl groups.

According to some aspects, the disclosure is directed to a slurry composition for a chemical mechanical polishing (CMP) process, the slurry composition comprising: about 0.1% by weight to about 10% by weight of polishing particles; about 0.001% by weight to about 1% by weight of an amine compound; about 0.001% by weight to about 1% by weight of a first cationic compound that is amino acid; and about 1% by weight to about 5% by weight of non-ionic polyhydric alcohol including at least two hydroxyl groups, wherein a pH value of the slurry composition ranges from about 2 to about 6.

According to some aspects, the disclosure is directed to a slurry composition for a chemical mechanical polishing (CMP) process, the slurry composition comprising: about 0.1% by weight to about 10% by weight of polishing particles; about 0.001% by weight to about 1% by weight of an amine compound; about 0.001% by weight to about 1% by weight of a first cationic compound that is amino acid; and about 1% by weight to about 5% by weight of non-ionic polyhydric alcohol, wherein the non-ionic polyhydric alcohol is hydrocarbon having 4 to 20 carbon atoms and comprises 4 to 14 hydroxyl groups.

### BRIEF DESCRIPTION OF THE DRAWINGS

Embodiments of the inventive concept will be more clearly understood from the following detailed description taken in conjunction with the accompanying drawings in which:

FIG. 1 is a conceptual perspective view of a polishing apparatus capable of a chemical mechanical polishing (CMP) process;

FIGS. 2A to 2C are cross-sectional views illustrating a method of manufacturing and testing a sample for a pattern removal test, according to certain example embodiments; and

FIGS. 3A to 3G are cross-sectional views illustrating a method of polishing a film, according to an example embodiment.

### DETAILED DESCRIPTION OF THE EMBODIMENTS

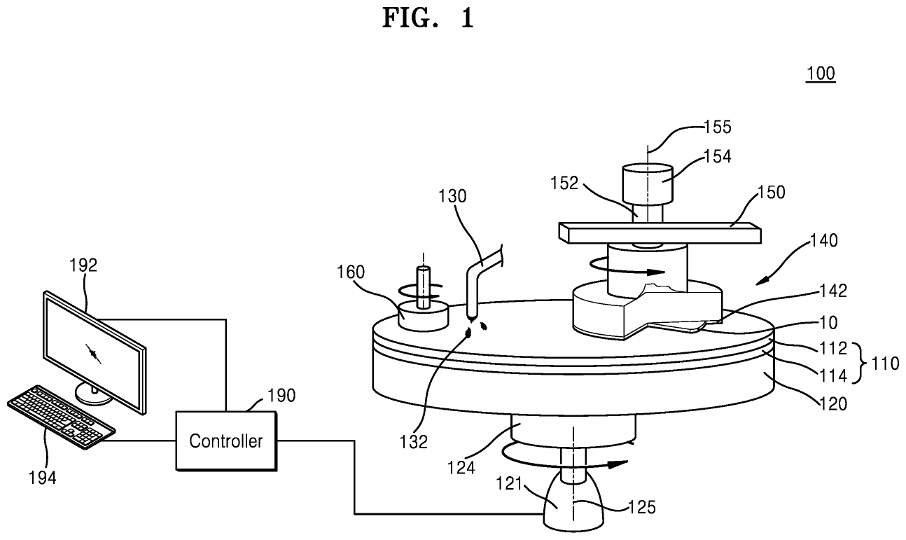

FIG. 1 is a conceptual perspective view of a polishing apparatus 100 capable of a chemical mechanical polishing (CMP) process.

Referring to FIG. 1, the polishing apparatus 100 may include a platen 120 having a rotating disc shape on which a polishing pad 110 is placed. The platen 120 may be capable of rotating about a central axis 125 thereof. For example, a motor 121 may turn a driving axis 124 to rotate the platen 120. The polishing pad 110 may be a polishing pad having at least two layers including an outer polishing layer 112 and a backing layer 114 that is more flexible than the outer polishing layer 112.

The polishing apparatus 100 may include a slurry port 130 configured to dispense a polishing agent 132 (e.g., slurry) toward the polishing pad 110. The polishing apparatus 100 may include a polishing pad conditioner 160 configured to condition the polishing pad 110 so that the polishing pad 110 may be maintained in a consistent polishing state. The polishing pad conditioner 160 may rotate around a central axis thereof

The polishing apparatus 100 may include at least one carrier head 140. The carrier head 140 may be configured to hold a substrate 10 against the polishing pad 110. The carrier head 140 may independently control polishing parameters (e.g., pressure) associated with each substrate.

In particular, the carrier head 140 may include a retaining ring 142 to hold the substrate 10 under a flexible membrane, which is provided at the lower region of the carrier head 140. For example, the retaining ring 142 may surround the substrate 10, causing the substrate 10 to be retained against the flexible membrane. The carrier head 140 may include a plurality of pressurizable chambers, which may be defined by the flexible membrane and controlled independently. The plurality of pressurizable chambers may independently apply controllable pressures to associated zones of the flexible membrane and the substrate 10.

The carrier head 140 may hang from a support structure 150 (e.g., a carousel or a track) and is connected to a carrier head rotational motor 154 by a driving axis 152, and the carrier head 140 may rotate about a central axis 155. Optionally, the carrier head 140 may oscillate in a lateral direction, for example, on a slider on the support structure 150 or the track or oscillate due to rotary oscillation of the support structure 150. During operation, the platen 120 may rotate about a central axis 125 thereof, and the carrier head 140 may rotate the central axis 155 thereof and be translated across a top surface of the polishing pad 110 in a lateral direction.

Although only one carrier head 140 is illustrated in FIG. 1, at least two carrier heads for maintaining additional substrates may be provided to efficiently use a surface area of the polishing pad 110.

The polishing apparatus 100 may also include a control system configured to control rotation of the platen 120. The control system may include a controller 190 (e.g., a general-use programmable digital computer), an output device 192 (e.g., a monitor), and an input device 194 (e.g., a keyboard).

Although FIG. 1 illustrates an example in which the control system is connected only to the motor 121, the control system may be also connected to the carrier head 140 and control a pressure or rotation speed of the carrier head 140. Furthermore, the control system may be connected to the slurry port 130 and control the supplying of slurry.

An embodiment provides a slurry composition for a CMP process, which may be used for the polishing apparatus 100.

The slurry composition for the CMP process may include about 0.1% by weight to about 10% by weight of polishing particles, about 0.001% by weight to about 1% by weight of an amine compound, about 0.001% by weight to about 1% by weight of a first cationic compound as amino acid, about 0.001% by weight to about 1% by weight of a second cationic compound as organic acid, and about 1% by weight to about 5% by weight of polyhydric alcohol.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

### Polishing Particles

The polishing particles may include an oxide, a nitride, or an oxynitride of a metal, but a material included in the polishing particles is not specifically limited. In particular, the metal may include at least one selected from the group consisting of silicon (Si), aluminum (Al), cerium (Ce), zirconium (Zr), germanium (Ge), manganese (Mn), magnesium (Mg), and titanium (Ti). In some embodiments, the polishing particles may include at least one selected from the group consisting of silica, ceria, zirconia, alumina, titania, barium titania, germania, mangania, and magnesia. In some embodiments, the polishing particles may be ceria, particularly, colloidal ceria synthesized from colloid.

A primary particle size of the polishing particles may have an average particle diameter of about 5 nm to about 150 nm, and a secondary particle size of the polishing particles may have an average particle diameter of about 30 nm to about 300 nm. An average particle diameter of the polishing particles may be measured by obtaining an average value of particle diameters of a plurality of particles within a visual range that may be measured by scanning electron microscope (SEM) analysis, Brunauer-Emmett-Teller (BET) analysis, or dynamic light scattering (DLS). The primary particle size may be about 150 nm or less to obtain particle uniformity, and a polishing rate may be reduced when the primary particle size is less than about 5 nm. When the secondary particle size is less than 30 nm, small particles may be excessively generated due to milling to lower cleaning power, and excessive defects may occur on a surface of a substrate or a wafer used for a polishing process. When the secondary particle size exceeds about 300 nm, an excessive polishing process may be performed to preclude the control of a polishing selectivity, and dishing, erosion, and surface defects may be likely to occur. The diameters of the particles references herein may be a ‘particle diameter’ indicating a distance between two farthest points of each polishing particle, and/or an ‘average diameter’ of the polishing particles indicating an arithmetic average of particle diameters of the polishing particles.

The polishing particles may include polishing particles prepared using a liquid method. The liquid method may be performed by applying a sol-gel method of causing a chemical reaction of a polishing particle precursor in a water solution and growing crystals to obtain fine particles, a co-precipitation reaction method of precipitating polishing particle ions in a water solution, or a hydrothermal synthesis method of forming polishing particles at a high temperature under a high pressure. The polishing particles prepared using the liquid method may be dispersed so that surfaces of the polishing particles may be positively charged.

The polishing particles may have a spherical shape, a rectangular shape, a needle shape, or a plate shape, but are not limited thereto.

The slurry composition for the CMP process may further include a dispersion medium for dispersing the polishing particles.

The dispersion medium may be an arbitrary liquid capable of substantially uniformly dispersing the polishing particles, but is not specifically limited. The dispersion medium may be an aqueous solvent or an organic solvent. More specifically, the dispersion medium may be an aqueous solvent, such as water, deionized water (DIW), and ultrapure water. Alternatively, the dispersion medium may be an organic solvent, such as aliphatic alcohols having 1 to 15 carbon atoms and ethers having 2 to 20 carbon atoms.

The slurry composition for the CMP process may contain about 0.1% by weight to about 10% by weight of the polishing particles based on a total weight of the slurry composition for the CMP process. In some embodiments, the slurry composition for the CMP process may contain about 0.3 to 8 parts by weight of the polishing particles based on 100 parts by weight of the slurry composition for the CMP process. In some embodiments, the slurry composition for the CMP process may contain about 0.5 to 7 parts by weight of the polishing particles based on 100 parts by weight of the slurry composition for the CMP process.

When the polishing particles are contained in an excessively low amount in the slurry composition for the CMP process, a polishing rate may be insufficient. When the polishing particles are contained in an excessively large amount in the slurry composition for the CMP process, a polishing selectivity may be reduced, and it may be difficult to control polishing quality and the polishing rate.

In some embodiments, surfaces of the polishing particles may be coated with an organic material or an inorganic material to exhibit a positive charge.

The organic material for coating the surfaces of the polishing particles may include, for example, at least one selected from the group consisting of amino acid, polyalkylene glycol, a polysaccharide conjugated with a glucosamine compound, and a polymer containing an amine group.

### Amine Compound

The amine compound may be a compound having 1 to 20 carbon atoms and having at least two amine groups in one molecule. In some embodiments, the amine compound may be diamine, triamine, tetramine, pentamine, hexamine, or heptamine.

In some embodiments, the amine compound may have 2 to 20 carbon atoms and include at least one nitrogen in a main chain of carbon.

The amine compound may include, for example, at least one selected from the group consisting of spermine, methane diamine, ethane-1,2-diamine, propane-1,3-diamine, butane-1,4-diamine, pentane-1,5-diamine, hexane-1,6-diamine, heptane-1,7-diamine, octane-1,8-diamine, diethylene triamine, dipropylene triamine, triethylenetetramine (TETA), tripropylene teramine, tetraethylenepentamine (TEPA), pentaethylenehexamine (PEHA), hexaethylene heptamine, bis(hexamethylene)triamine, N-(3-aminopropyl)ethylenediamine, N,N′-bis(3-aminopropyl)ethylenediamine, N,N-bis(2-aminoethyl)-1,3-propanediamine, N,N,N′-tris(3-aminopropyl)ethylenediamine, N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, N,N,N′N′-tetrakis(2-hydroxypropyl) ethylenediamine, N,N,N′,N′-tetramethylpropanediamine, di-t-butylethylenediamine, 3,3′-iminobis(propylamine), N-methyl-3,3′-iminobis(propylamine), N,N′-bis(3-aminopropyl)-1,3-propylenediamine, N,N′-bis(3-aminopropyl)-1,4-butylenediamine, N,N′-bis(4-aminobutyl)-1,4-butanediamine, N,N′-bis(2-aminoethyl)-1,4-butanediamine, N,N′-bis(2-aminoethyl)ethylenediamine, bis(3-aminopropyl)amine, bis(4-aminobutyl)amine, bis(5-aminopentyl)amine, N-(6-aminohexyl)-1,6-hexanediamine, hexahydro-1,3,5-triazine, N-methylethylenediamine, N-ethylethylenediamine, N-propylethylenediamine, N-butylethylenediamine, N-methyl-1,3-diaminopropane, N-methyl-1,4-diaminobutane, N-methyl-1,5-diaminopentane, N-methyl-1,6-diaminohexane, N-methyl-1,7-diaminoheptane, N-methyl-1,8-diaminooctane, N-methyl-1,9-diaminononane, N-methyl-1,10-diaminodecane, N-methyl-1,11-diaminoundecane, N-methyl-1,12-diaminododecane, 1,3-bis(aminomethyl)cyclohexane, 1,4-bis(aminomethyl)cyclohexane, piperazine, and derivatives thereof, but is not limited thereto.

The amine compound may be contained in an amount of about 0.001% by weight to about 1% by weight based on a total weight of the slurry composition for the CMP process. In some embodiments, the amine compound may be contained in an amount of about 0.005% by weight to about 0.5% by weight based on a total weight of the slurry composition for the CMP process. In some embodiments, the amine compound may be contained in an amount of about 0.01% by weight to about 0.1% by weight based on a total weight of the slurry composition for the CMP process.

The amine compound may inhibit dishing from occurring on a surface of silicon oxide.

When content of the amine compound in the slurry composition for the CMP process is excessively low, a dishing phenomenon may excessively occur. When the content of the amine compound in the slurry composition for the CMP process is excessively high, the stability of the slurry composition may deteriorate.

### First Cationic Compound

The first cationic compound may be an amino acid compound. For example, the first cationic compound may include at least one selected from the group consisting of arginine, lysine, histidine, aspartic acid, glutamic acid, asparagine, glutamine, tyrosine, serine, cysteine, threonine, glycine, alanine, β-alanine, proline, tryptophan, methionine, phenylalanine, valine, leucine, and isoleucine, but is not limited thereto.

Since the first cationic compound contains a positively charged amine group and a negatively charged carboxylic acid, the first cationic compound may protect surfaces of silicon oxide and silicon nitride.

The first cationic compound may be contained in an amount of about 0.001% by weight to about 1% by weight based on a total weight of the slurry composition for the CMP process. In some embodiments, the first cationic compound may be contained in an amount of about 0.005% by weight to about 0.5% by weight based on a total weight of the slurry composition for the CMP process. In some embodiments, the first cationic compound may be contained in an amount of about 0.01% by weight to about 0.1% by weight based on a total weight of the slurry composition for the CMP process.

When the first cationic compound is contained in an excessively low amount in the slurry composition for the CMP process, the polishing stop performance of a polishing stop layer may be degraded to reduce a polishing selectivity. When the first cationic compound is contained in an excessively high amount in the slurry composition for the CMP process, the stability of the slurry composition may be reduced.

### Second Cationic Compound

The second cationic compound may be organic acid and may control a pH value of the slurry composition for the CMP process.

The second cationic compound may include, for example, at least one selected from the group consisting of pimelic acid, malic acid, malonic acid, maleic acid, acetic acid, 2,2-dichloroacetic acid, trifluoroacetic acid, pelargonic acid, valeric acid, enanthic acid, myristic acid, azelaic acid, adipic acid, orotic acid, oxalic acid, succinic acid, mercaptosuccinic acid, alginic acid, tartaric acid, carbonic acid, cinnamic acid, citric acid, lactic acid, lactobionic acid, glutaric acid, 2-oxo-glutaric acid, glucoheptonic acid, gluconic acid, glucuronic acid, glutamic acid, pyroglutamic acid, glycolic acid, formic acid, fumaric acid, palmitic acid, pamoic acid, propionic acid, butyric acid, hydroxybutyric acid, ascorbic acid, aspartic acid, aspartic acid, stearic acid, thiocyanic acid, itaconic acid, tricarballyic acid, pyruvic acid, suberic acid, benzenesulfonic acid, benzoic acid, 4-acetamidobenzoic acid, 4-(4-hydroxyphenyl)benzoic acid, phenylacetic acid, phenylene diacetic acid, diethylmalonic acid, phenylmalonic acid, phenylene dibutyrate, p-phenylene dicarboxylic acid, 4,4′-diphenyl ether carboxylic acid, 1,5-naphthalene dicarboxylic acid, 2,6-naphthalene dicarboxylic acid, 4′-hydroxy-4-biphenylcarboxylic acid, naphthoic acid, 1-hydroxy-2-naphthoic acid, 6-hydroxy-1-naphthoic acid, mandelic acid, nicotinic acid, gentisic acid, nicotinic acid, isonicotinic acid, quinolinic acid, anthranilic acid, fusaric acid, capric acid, caproic acid, caprylic acid, dodecylsulfuric acid, camphoric acid, camphor-10-sulfonic acid, ethane-1,2-disulfonic acid, methanesulfonic acid, ethanesulfonic acid, 2-hydroxyethanesulfonic acid, p-toluenesulfonic acid, naphthalene-1,5-disulfonic acid, naphthalene-2-sulfonic acid, phthalic acid, isophthalic acid, salicylic acid, 4-aminosalicylic acid, terephthalic acid, lauric acid, mucic acid, oleic acid, cyclamic acid, galactaric acid, hippuric acid, glycerophosphoric acid, sebacic acid, undecylenic acid, mellitic acid, trimellitic acid, pyromellitic acid, pyromellitic acid anhydride, and pyridinecarboxylic acid, but is not limited to the above-described organic acids.

The second cationic compound may be contained in the slurry composition for the CMP process at such content that a pH value of the slurry composition for the CMP process ranges from about 2 to about 6. In some embodiments, the second cationic compound may be contained in an amount of about 0.001% by weight to about 1% by weight based on a total weight of the slurry composition for the CMP process.

When the second cationic compound is contained in an excessively large or small amount in the slurry composition for the CMP process, a pH value of the slurry composition for the CMP process may be excessively low or high. In this case, a polishing rate may be insufficient or dishing may occur excessively.

### Sugar Alcohol Compound

The sugar alcohol compound may be a non-ionic compound, which is polyhydric alcohol obtained by reducing saccharides, particularly, monosaccharides or disaccharides. Since the sugar alcohol compound is the non-ionic compound, an electrostatic reaction of the sugar alcohol compound with a polished surface may be substantially excluded. Also, the sugar alcohol compound may be hydrogen bonded to a nitrogen (N)-terminal on a silicon nitride surface and/or an oxygen (O)-terminal on a silicon oxide surface.

The sugar alcohol compound may be polyhydric alcohol including at least two hydroxyl groups. In some embodiments, the sugar alcohol compound may be a hydrocarbon compound having 4 to 20 carbon atoms and including 4 to 14 hydroxyl groups. In some embodiments, the sugar alcohol compound may have a structure of Formula 1:

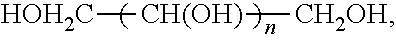

wherein n is an integer ranging from 2 to 12.

In some embodiments, the sugar alcohol compound may be a compound having a structure of Formula 2:

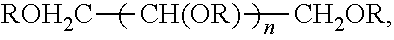

wherein n is an integer ranging from 2 to 12, and R is respectively hydrogen or a substituent of Formula 3:

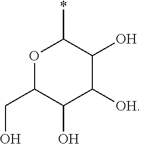 [SMILES: *C1OC(CO)C(O)C(O)C1O]

In some embodiments, one or two of a plurality of Rs (i.e., (n+2)R) of the compound of Formula 2 may be substituents of Formula 3. In some embodiments, at least one of the plurality of Rs (i.e., (n+2)R) of the compound of Formula 2 may be the substituent of Formula 3.

As can be seen from Formula 1, the sugar alcohol compound may include at least one C4 moiety in which four carbon atoms are continuously connected in a linear chain. Specifically, each of the compounds of Formula 1 and Formula 2, according to example embodiments, may include at least one C4 moiety in which at least four carbon atoms are continuously connected in a linear chain (see, for example, the insides of the rectangular boxes) as shown in Formula 4:

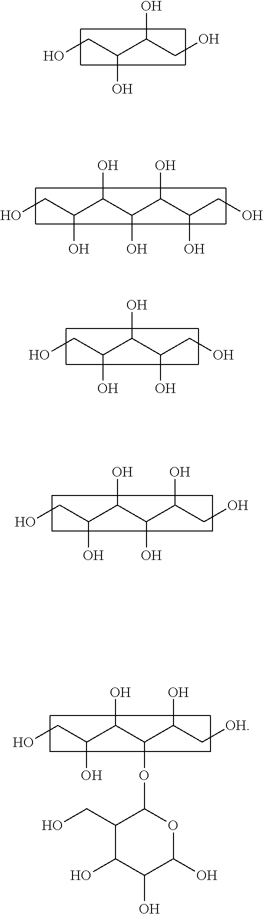 [SMILES: OCC(O)C(O)CO ; OCC(O)C(O)C(O)C(O)C(O)CO ; OCC(O)C(O)C(O)CO ; OCC(O)C(O)C(O)C(O)CO ; OCC(O)C(O)C(OC1OC(O)C(O)C(O)C1CO)C(O)CO]

In some embodiments, the sugar alcohol compound may be, for example, at least one selected from the group consisting of maltitol, lactitol, threitol, erythritol, ribitol, xylitol, arabitol, adonitol, sorbitol(=glucitol), talitol(=altritol), isomalt, mannitol, iditol, allodulcitol, dulcitol(=galactitol), sedoheptitol(=volemitol), and perseitol, but is not limited thereto.

As described above, since the sugar alcohol compound is the non-ionic compound, the electrostatic reaction of the sugar alcohol compound with the polished surface may be substantially prevented and the sugar alcohol compound may be hydrogen bonded to the silicon oxide surface and/or the silicon nitride surface.

Although the disclosed embodiments are not limited by a specific theory, since a hydrogen bond strength (about 29 kJ/mol) between the sugar alcohol compound and nitrogen of silicon nitride is higher than a hydrogen bond strength (about 21 kJ/mol) between the sugar alcohol compound and oxygen of silicon oxide, it can be inferred that the slurry composition for the CMP process may contribute to improving a polishing selectivity of silicon nitride.

When a pH value of the slurry composition for the CMP process is adjusted to the range of 2 to 6, a zeta potential of silicon oxide may be negative. A positive charge of the first cationic compound and a hydroxyl group of the sugar alcohol compound may be competitively adsorbed on silicon oxide. As a result, it is estimated that even if some hydrogen bonds are formed between the hydroxyl group of the sugar alcohol compound and silicon oxide, a polishing rate of silicon oxide is not sacrificed.

For example, it has been found that the sugar alcohol compound was bonded to the surface of silicon nitride to increase a polishing selectivity together with the first cationic compound and the amine compound, and dishing was effectively inhibited from occurring on the surface of silicon oxide.

The sugar alcohol compound may be contained in an amount of about 1% by weight to about 5% by weight based on a total weight of the slurry composition for the CMP process. Alternatively, the sugar alcohol compound may be contained in an amount of about 1.3% by weight to about 4.5% by weight based on a total weight of the slurry composition for the CMP process. Alternatively, the sugar alcohol compound may be contained in an amount of about 1.5% by weight to about 4.0% by weight based on a total weight of the slurry composition for the CMP process.

If the sugar alcohol compound is contained in an excessively low amount in the slurry composition for the CMP process, the sugar alcohol may not sufficiently contribute to improving a polishing selectivity. If the sugar alcohol compound is contained in an excessively large amount in the slurry composition for the CMP process, a polishing rate may be excessively reduced.

In addition, the slurry composition for the CMP process according to the embodiments may further include a surfactant, a dispersing stabilizer, a polishing inhibitor, and a leveling agent.

### Surfactant

The slurry composition for the CMP process may further include a surfactant as needed. The surfactant may be any one of a non-ionic surfactant, a cationic surfactant, an anionic surfactant, and an amphoteric surfactant.

The non-ionic surfactant may be polyoxyethylene alkylethers such as polyoxyethylene laurylether and polyoxyethylene stearylether; polyoxyethylene alkylphenylethers such as polyoxyethylene octylphenylether and polyoxyethylene nonyl phenylether; sorbitan monolaurate, sorbitan higher fatty acid esters such as sorbitan monostearate and sorbitan trioleate; polyoxyethylene sorbitan higher fatty acid esters such as polyoxyethylene sorbitan monolaurate; polyoxyethylene higher fatty acid esters such as polyoxyethylene monolaurate and polyoxyethylene monostearate; glycerine higher fatty acid esters such as oleic acid monoglyceride and stearic acid monoglyceride, polyoxyalkylenes such as polyoxyethylene, polyoxypropylene, and polyoxybutylene, and block copolymers thereof.

The cationic surfactant may be alkyl trimethyl ammonium chloride, dialkyl dimethyl ammonium chloride, benzalkonium chloride, or alkyl dimethyl ammonium ethosulfate.

The anionic surfactant may be carboxylic acid salts such as lauric acid sodium, oleic acid sodium, N-acyl-N-methylglycine sodium salt, and polyoxyethylene laurylether carboxylic acid sodium, sulfonates such as dodecylbenzene sulfonic acid sodium, sulfonic acids such as dialkyl sulfosuccinate ester salt and dimethyl-5-sulfoisophthalate sodium, sulfate ester salts such as sodium lauryl sulphate (SLS), sodium lauryl polyoxyethylene ether sulphate, and polyoxyethylene nonylphenyl ether sodium sulfate, and phosphate ester salts such as polyoxyethylene lauryl sodium phosphate, polyoxyethylene nonylphenyl ether sodium phosphate.

The amphoteric surfactant may be a carboxybetaine surfactant, aminocarboxylic acid, imedazolinium betaine, lecithin, or alkylamineoxide.

The surfactant may be mixed in an amount of about 0.001% by weight to about 0.5% by weight based on a total weight of the slurry composition for the CMP process.

### Dispersing Stabilizer

The slurry composition for the CMP process may further include a dispersing stabilizer to ensure dispersion stability of polishing particles. The dispersing stabilizer may include a non-ionic polymer or a cationic organic compound. For example, the dispersing stabilizer may include at least one selected from the group consisting of ethylene oxide, ethylene glycol, glycol distearate, glycol monostearate, glycol polymerate, glycol ethers, alkyl amine-containing alcohols, polymerate ether-containing compounds, vinyl pyrrolidone, celluloses, and ethoxylate-based compounds. Specifically, the dispersing stabilizer may include at least one selected from the group consisting of diethylene glycol hexadecyl ether, decaethylene glycol hexadecyl ether, diethylene glycol octadecyl ether, eicosaethylene glycol octadecyl ether, diethylene glycol oleyl ether, decaethylene glycol oleyl ether, decaethylene glycol octadecyl ether, nonylphenol polyethylene glycol ether, ethylenediamine tetrakis(ethoxylate-block-propoxylate) tetrol, ethylenediamine tetrakis(propoxylate-block-ethoxylate) tetrol, polyethylene-block-poly(ethylene glycol), polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylenesorbitan monolaurate, sorbitan monopalmitate, FS-300 non-ionic fluorosurfactant, FSN non-ionic fluorosurfactant, FSO non-ionic ethoxylated fluorosurfactant, vinyl pyrrolidone, celluloses, 2,4,7,9-Tetramethyl-5-decyne-4,7-diol ethoxylate, 8-methyl-1-nonanol propoxylate-block-ethoxylate, allyl alcohol 1,2-butoxylate-block-ethoxylate, polyoxyethylene branched nonylcyclohexyl ether, or polyoxyethylene isooctylcyclohexyl ether. For example, the dispersing stabilizer may be mixed in an amount of about 0.1% by weight to about 1% by weight based on a total weight of the slurry composition for the CMP process.

### Polishing Inhibitor

The slurry composition for the CMP process may further include a polishing inhibitor as needed.

Non-limiting examples of the polishing inhibitor may be a nitrogen-containing compound (e.g., amine) and a heterocyclic compound (e.g., benzotriazole, 1,2,3-triazole, and 1,2,4-triazole) containing a low-molecular-weight nitrogen.

The polishing inhibitor may be mixed in an amount of about 0.1% by weight to about 1% by weight based on a total weight of the slurry composition for the CMP process.

### Leveling Agent

The slurry composition for the CMP process may further include a leveling agent for reducing irregularities of a polished surface as needed.

Non-limiting examples of the leveling agent may include ammonium chloride, ammonium lauryl sulfate (ALS), polyethyleneglycol, polyoxyethylene alkyl ether sulfate (AES) triethylamine, polyvinylpyrrolidone (PVP), and polyacrolein.

The leveling agent may be mixed in an amount of about 0.1% by weight to about 1% by weight based on a total weight of the slurry composition for the CMP process.

When the slurry compositions for the CMP process according to the embodiments are used, an improved polishing selectivity with respect to silicon nitride-silicon oxide may be obtained without sacrificing a polishing rate of a material film, and a dishing phenomenon may be effectively inhibited. Also, since colloid polishing particles are used, a high-quality surface with few scratches may be obtained.

Constructions and effects of the disclosed embodiments will now be described in further detail with reference to specific experimental examples and comparative examples. The following experimental examples are provided for simplicity, and the disclosed embodiments are not limited thereto.

The colloidal ceria, the first cationic compound, the amine compound, and the sugar alcohol compound were mixed at a mixing ratio shown in Table 1 in DIW, and oxalic acid was added so that a pH value of the slurry composition for the CMP process would be 3. Content of the colloidal ceria was maintained in a constant amount of 4% by weight.

TABLE 1

| | First cationic | | Amine | | Sugar alcohol | |
|---|---|---|---|---|---|---|
| | compound (wt %) | | compound (wt %) | | compound (wt %) | |
| Experimental | histidine | 0.056 | PEHA | 0.005 | sorbitol | 1 |
| example 1 | | | | | | |
| Experimental | arginine | 0.056 | PEHA | 0.005 | sorbitol | 1.5 |
| example 2 | | | | | | |
| Experimental | histidine | 0.056 | spermine | 0.005 | sorbitol | 1.5 |
| example 3 | | | | | | |
| Experimental | histidine | 0.056 | TETA | 0.09 | sorbitol | 1.5 |
| example 4 | | | | | | |
| Experimental | histidine | 0.056 | TEPA | 0.06 | sorbitol | 1.5 |
| example 5 | | | | | | |
| Experimental | histidine | 0.056 | PEHA | 0.005 | sorbitol | 1.5 |
| example 6 | | | | | | |
| Experimental | histidine | 0.056 | PEHA | 0.005 | sorbitol | 1.75 |
| example 7 | | | | | | |
| Experimental | arginine | 0.056 | PEHA | 0.005 | sorbitol | 2 |
| example 8 | | | | | | |
| Experimental | histidine | 0.056 | PEHA | 0.005 | sorbitol | 2 |
| example 9 | | | | | | |
| Experimental | histidine | 0.056 | PEHA | 0.005 | sorbitol | 2.5 |
| example 10 | | | | | | |
| Experimental | arginine | 0.056 | PEHA | 0.005 | sorbitol | 3 |
| example 11 | | | | | | |
| Experimental | histidine | 0.056 | PEHA | 0.005 | sorbitol | 3 |
| example 12 | | | | | | |
| Experimental | histidine | 0.056 | PEHA | 0.005 | sorbitol | 4.5 |
| example 13 | | | | | | |
| Experimental | histidine | 0.056 | BHMTA | 0.005 | sorbitol | 4.8 |
| example 14 | | | | | | |
| Experimental | glutamine | 0.6 | HEHA | 0.05 | lactitol | 1.5 |
| example 15 | | | | | | |
| Experimental | lysine | 0.8 | spermine | 0.1 | ribitol | 1.5 |
| example 16 | | | | | | |
| Experimental | glycine | 0.84 | TETA | 0.3 | arabitol | 1.5 |
| example 17 | | | | | | |
| Experimental | valine | 0.88 | TEPA | 0.5 | xylitol | 1.5 |
| example 18 | | | | | | |
| Comparative | histidine | 0.056 | PEHA | 0.005 | — | — |
| example 1 | | | | | | |
| Comparative | histidine | 0.056 | PEHA | 0.005 | sorbitol | 0.5 |
| example 2 | | | | | | |
| Comparative | histidine | 0.056 | PEHA | 0.005 | sorbitol | 5.5 |
| example 3 | | | | | | |
| Comparative | histidine | 0.056 | BHMTA | 0.005 | sorbitol | 5.2 |
| example 4 | | | | | | |
| Comparative | histidine | 0.056 | spermine | 0.005 | — | — |
| example 5 | | | | | | |

PEHA: pentaethylenehexamine
TETA: triethylenetetramine
TEPA: tetraethylenepentamine
BHMTA: bis(hexamethylene)triamine
HEHA: hexaethyleneheptamine

Polishing experiments were conducted using slurry compositions for a CMP process, which are prepared at mixing ratios shown in Table 1.

Samples in which silicon oxide (Si oxide) and silicon nitride (Si nitride) were formed on silicon substrates were used as samples for testing a non-pattern removal rate. Variations in thicknesses of silicon oxide and silicon nitride were measured before and after a polishing process, and removal rates were calculated, and the thickness variations and the removal rates were arranged in Table 2.

A sample in which 100-μm silicon oxide and 100-μm silicon nitride were alternately formed in a line-and-space form and a sample in which 90-μm silicon oxide and 10-μm silicon nitride were alternately formed in a line-and-space form were used as samples for a pattern removal test.

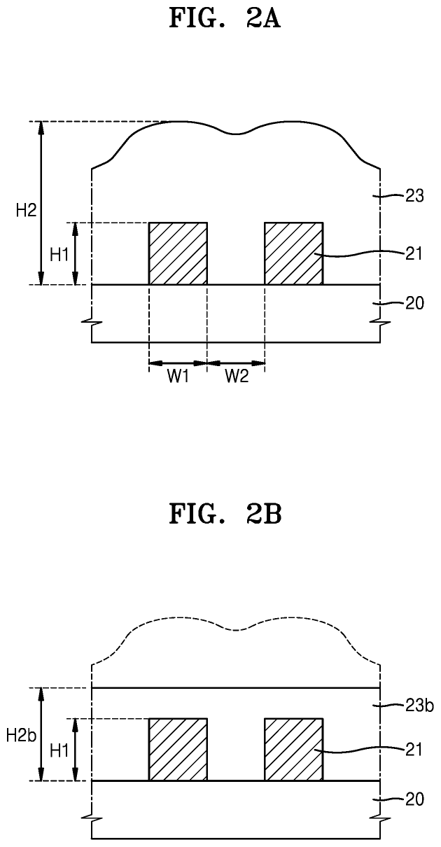

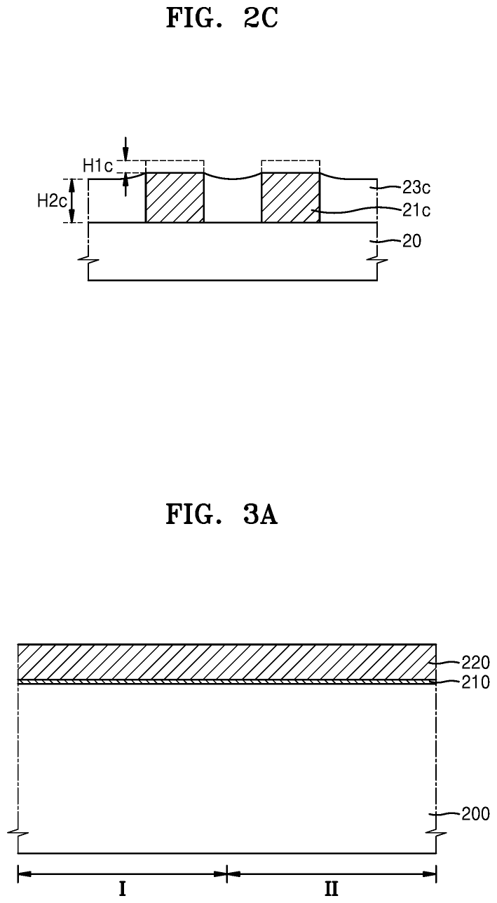

FIGS. 2A to 2C are cross-sectional views illustrating a method of manufacturing and testing a sample for a pattern removal test.

Referring to FIG. 2A, line patterns 21 including silicon nitride, each of which has a first width W1, may be formed on a silicon substrate 20 at intervals of a second width W2. The line patterns 21 including silicon nitride may have a first height H1. Also, a silicon oxide layer 23 may be formed on the line patterns 21 to have a second height H2. The second height H2 may be a maximum height of the silicon oxide layer 23 relative to a top surface of the silicon substrate 20.

In the present experiment, the first height H1 was about 100 angstroms (Å), and the second height H2 was about 2000 Å. Also, a sample (100μm/100μm) having the first width W1 of about 100 μm and the second width W2 of about 100 μm and a sample (10 μm/90 μm) having the first width W1 of about 10 μm and the second width W2 of about 90 μm were each manufactured.

Referring to FIG. 2B, an upper portion of the silicon oxide layer 23 may be partially removed to remove an initial step difference so that a height H2b of the silicon oxide layer 23b may be about 1300 Å. For example, the upper portion of the silicon oxide layer 23 may be partially removed to provide a uniform height H2b of the silicon oxide layer 23b relative to the top surface of the silicon substrate 20.

Referring to FIG. 2C, a polishing process was performed using the slurry composition for the CMP process, according to the experimental examples and the comparative examples.

AP-300 (manufactured by CTS) was used as polishing equipment, and a table revolutions-per-minute (table RPM) was adjusted to 47 and a spindle RPM was adjusted to 53 for about 60 seconds. A supply flow rate of the slurry composition was adjusted to about 300 ml/min, and a pressure applied to a pad was about 4.0 psi.

As a result, upper portions of line patterns 21c including silicon nitride had a loss corresponding to a height H1c. Meanwhile, even after the upper portions of the line patterns 21c were exposed, a silicon oxide layer 23c was over-polished to some extent, so the silicon oxide layer 23c having a remaining height H2c was obtained along with slight dishing.

Heights H1c (\textcircled{1}) and H2c (\textcircled{2}) of the 100 μm/100 μm sample and a height H2c (\textcircled{3}) of the 10 μm/90 μm sample were measured and arranged in Table 2.

TABLE 2

| | Non-pattern removal | | Pattern removal | | |
|---|---|---|---|---|---|
| | rate (Å/min) | | result (Å) | | |
| | Si oxide | Si nitride | \textcircled{1} | \textcircled{2} | \textcircled{3} |
| Experimental example 1 | 2034 | 28 | 29 | 947 | 887 |
| Experimental example 2 | 1940 | 28 | 31 | 1008 | 801 |
| Experimental example 3 | 1678 | 28 | 29 | 998 | 795 |
| Experimental example 4 | 2578 | 34 | 31 | 951 | 547 |
| Experimental example 5 | 2058 | 29 | 29 | 987 | 768 |
| Experimental example 6 | 1940 | 28 | 29 | 1035 | 912 |
| Experimental example 7 | 1894 | 29 | 28 | 1037 | 938 |
| Experimental example 8 | 1867 | 29 | 32 | 1015 | 824 |
| Experimental example 9 | 1840 | 27 | 28 | 1040 | 957 |
| Experimental example 10 | 1648 | 27 | 28 | 1043 | 967 |
| Experimental example 11 | 1418 | 30 | 30 | 1021 | 865 |
| Experimental example 12 | 1381 | 26 | 27 | 1063 | 1020 |
| Experimental example 13 | 1157 | 26 | 26 | 1066 | 1023 |
| Experimental example 14 | 1054 | 27 | 25 | 1112 | 1025 |
| Experimental example 15 | 1864 | 35 | 34 | 978 | 798 |
| Experimental example 16 | 1789 | 26 | 27 | 919 | 801 |
| Experimental example 17 | 1950 | 29 | 31 | 957 | 814 |
| Experimental example 18 | 2209 | 31 | 30 | 923 | 751 |
| Comparative example 1 | 2120 | 29 | 75 | 545 | 155 |
| Comparative example 2 | 2448 | 37 | 48 | 687 | 315 |
| Comparative example 3 | 417 | 25 | — | — | — |
| Comparative example 4 | 676 | 27 | — | — | — |
| Comparative example 5 | 2124 | 28 | 71 | 623 | 224 |

| | |
|---|---|
| \textcircled{1}: | 100 μm/100 μm nitrate loss |
| \textcircled{2}: | 100 μm/100 μm remaining oxide |
| \textcircled{3}: | 10 μm/90 μm remaining oxide |

As shown in Table 2, the slurry compositions for the CMP process according to the embodiments could obtain generally high removal rates and dishing inhibition effects. In contrast, when a sugar alcohol compound was not contained (see Comparative examples 1 and 5) and when a sugar alcohol compound (sorbitol) was contained, but in an excessively low content (see comparative example 2), it was observed that dishing occurred at increased amounts and a height of residual oxide was considerably lower.

When the sugar alcohol compound (sorbitol) was contained in an excessively large amount (comparative example 3), a non-pattern removal rate test showed that a polishing selectivity was markedly degraded and a removal state was excessively reduced. In Comparative example 3, a pattern removal test was not performed because a removal rate of a material film was too low.

### Method of Polishing Film

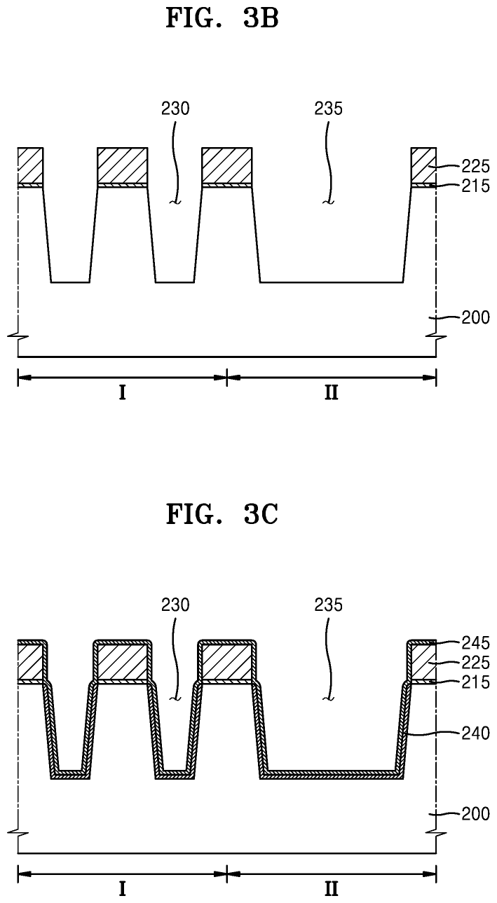

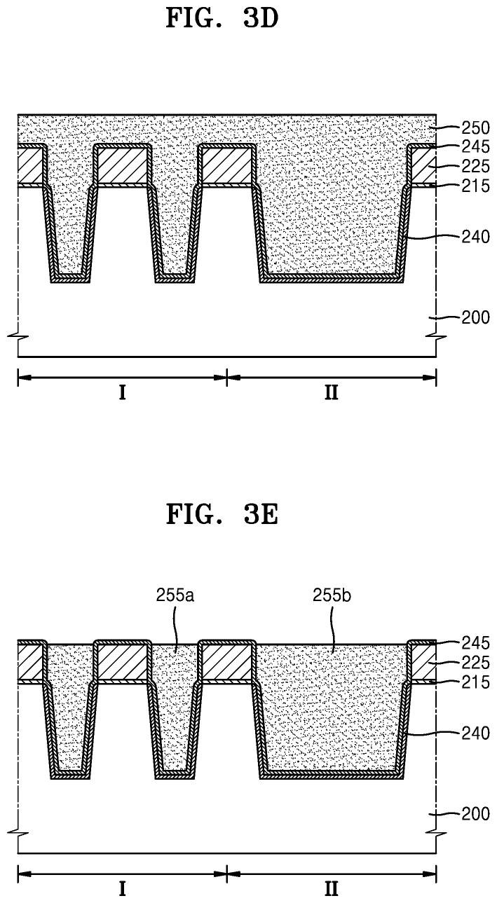

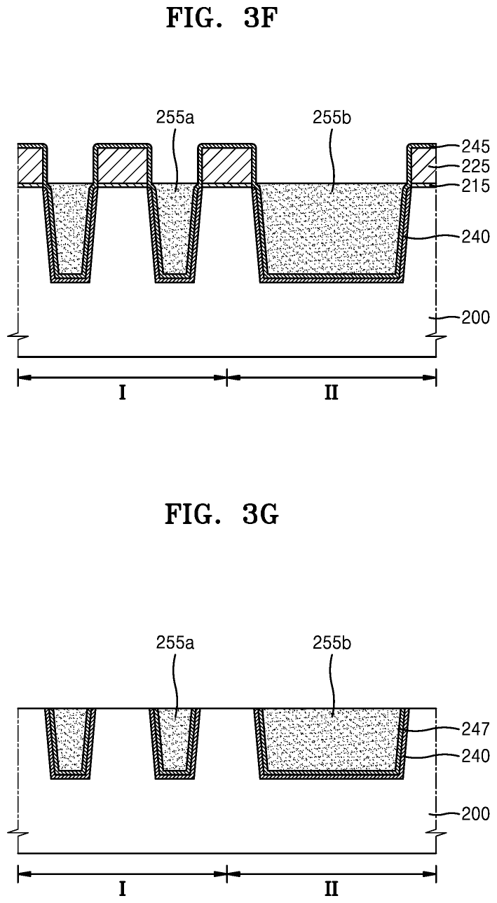

FIGS. 3A to 3G are cross-sectional views illustrating a method of polishing a film, according to an example embodiment. For example, FIGS. 3A to 3G illustrate a shallow trench isolation (STI) process using the slurry compositions for the CMP process according to the above-described example embodiments.

Referring to FIG. 3A, a pad oxide film 210 and a mask film 220 may be formed on a substrate 200.

The substrate 200 may include a semiconductor substrate, such as a silicon substrate, a germanium substrate, or a silicon-germanium substrate, a silicon-on-insulator (SOI) substrate, and a germanium-on-insulator (GOI) substrate. The substrate 200 may include a Group III-V compound, such as indium phosphide (InP), gallium phosphide (GaP), gallium arsenide (GaAs), and gallium antimony (GaSb). Although not shown in the drawings, p-type or n-type impurities may be implanted into an upper portion of the substrate 200 to form a well.

The substrate 200 may be divided into a first region I and a second region II. In some embodiments, the first region I of the substrate 200 may be allocated to a device region in which a memory device and a logic device are formed. The second region II of the substrate 200 may be allocated to a peripheral circuit region.

Each of the pad oxide film 210 and the mask film 220 may include silicon oxide and silicon nitride. The pad oxide film 210 and the mask film 220 may be formed using a deposition process, such as a chemical vapor deposition (CVD) process, a sputtering process, and an atomic layer deposition (ALD) process. In some embodiments, the pad oxide film 210 may be formed by thermally oxidizing a top surface of the substrate 200.

Referring to FIG. 3B, upper portions of the substrate 200 may be etched to form a first trench 230 and a second trench 235.

According to example embodiments, the mask film 220 and the pad oxide film 210 may be partially removed using a photolithography process to form a mask pattern 225 and a pad oxide film pattern 215, respectively. The upper portions of the substrate 200 may be removed through an STI process using the mask pattern 225 and the pad oxide film pattern 215 as an etch mask to form the first and second trenches 230 and 235.

The first trench 230 and the second trench 235 may be respectively formed in the first region I and the second region II of the substrate 200. For example, the second trench 235 formed in the peripheral circuit region may be formed to have a greater width than that of the first trench 230 formed in the device region.

In some example embodiments, a pattern density, which is defined as a ratio of a total area of the first and second trenches 230 and 235 to a unit area of the substrate 200 may range from about 5% to about 10%.

Referring to FIG. 3C, a liner may be formed on sidewalls of the first and second trenches 230 and 235.

According to example embodiments, a first liner 240 may be formed on exposed sidewalls of the first and second trenches 230 and 235 using, for example, a thermal oxidation process. For example, the first liner 240 may include silicon oxide.

Thereafter, a second liner 245 may be conformally formed on surfaces of the first liner 240, the pad oxide film pattern 215, and the mask pattern 225. The second liner 245 may be formed of silicon nitride using, for example, a CVD process and an ALD process.

Referring to FIG. 3D, a device isolation film 250 may be formed on the second liner 245 to sufficiently fill the first and second trenches 230 and 235. The device isolation film 250 may be formed of a silicon oxide-based material, such as plasma-enhanced oxide (PEOX), tetraethyl orthosilicate (TEOS), and flowable oxide (FOX), using a CVD process.

Referring to FIG. 3E, an upper portion of the device isolation film 250 may be planarized using the CMP slurry compositions according to the above-described example embodiments. For example, the CMP process using the CMP slurry composition may be performed using the second liner 245 or the mask pattern 225 as a polishing stop film to remove the upper portion of the device isolation film 250.

Thus, the device isolation film 250 may be divided into a first device isolation film 255a and a second device isolation film 255b. The first device isolation film 255a may fill the first trench 230 in the first region I, and the second device isolation film 255b may fill the second trench 235 in the second region II.

As described above, the slurry composition for the CMP process may contain about 0.1% by weight to about 10% by weight of the polishing particles; about 0.001% by weight to about 1% by weight of the amine compound; about 0.001% by weight to about 1% by weight of the first cationic compound that is amino acid; and about 1% by weight to about 5% by weight of non-ionic polyhydric alcohol including at least two hydroxyl groups. Also, the slurry composition for the CMP process may further include organic acid for controlling a pH value as a second cationic compound.

The polishing particles may be colloid polishing particles, which are dispersed so that the colloid polishing particles may be positively charged. The polishing particles may remove silicon oxide relatively rapidly in a pH range of about 2 to about 6, and a high-quality surface with few scratches may be obtained.

Since a sugar alcohol compound obtained by reduction of saccharides such as monosaccharides or disaccharides is non-ionic, the sugar alcohol compound may be hydrogen bonded to the surface of silicon nitride to improve a polishing selectivity.

In addition, a polishing rate may be controlled by attaching a first cationic compound to a surface of silicon oxide, so that occurrence of dishing on the surface of silicon oxide may be suppressed.

As described above, due to an interaction between the first cationic compound, an amine compound, and a non-ionic sugar alcohol compound, the slurry composition for the CMP process may have a high polishing selectivity of an oxide film with respect to a nitride film and reduce the occurrence of dishing on the oxide film.

Thus, the occurrence of dishing may be inhibited even in the second region II having a relatively large pattern width (e.g., widths of trenches) so that the first device isolation film 255a and the second device isolation film 255b having substantially coplanar top surfaces may be formed in the first region I and the second region II.

In some embodiments, top surfaces of the first device isolation film 255a and the second device isolation film 255b may be at substantially the same level as a top surface of the mask pattern 225.

Referring to FIG. 3F, for example, upper portions of the first device isolation film 255a and the second device isolation film 255b may be removed using an etchback process or an additional CMP process. In some embodiments, top surfaces of the first device isolation film 255a and the second device isolation film 255b may be coplanar with a top surface of the pad oxide film pattern 215.

Referring to FIG. 3G, an upper portion of the second liner 245, the hard mask pattern 225, and the pad oxide film pattern 215 may be removed. In some embodiments, the first device isolation film 255a and the second device isolation film 255b may be further polished or planarized so that the top surface of the substrate 200 is exposed.

Thus, the first liner 240 and the second liner pattern 247 may remain inside the first and second trenches 230 and 235 to form the first device isolation film 255a and the second device isolation film 255b, which may be substantially coplanar with the top surface of the substrate 200.

As described above, by using a polishing composition according to example embodiments, polishing efficiency may be improved while inhibiting the dishing of an oxide film (e.g., the device isolation film 250). Thus, for example, in subsequent processes described with reference to FIGS. 3F to 3G, a process of polishing the first device isolation film 255a and the second device isolation film 255b may be controlled, and a reliable device isolation process may be implemented.

Further processes may be performed on the wafer, for example to form a semiconductor device. For example, additional conductive and insulating layers may be deposited on the wafer to form semiconductor chips, the semiconductor chips may then be singulated, packaged on a package substrate, and encapsulated by an encapsulant to form a semiconductor package.

While the inventive concept has been particularly shown and described with reference to embodiments thereof, it will be understood that various changes in form and details may be made therein without departing from the spirit and scope of the following claims.

What is claimed is:

1. A slurry composition for a chemical mechanical polishing (CMP) process, the slurry composition comprising:
about 0.1% by weight to about 10% by weight of polishing particles;
about 0.001% by weight to about 1% by weight of an amine compound;
about 0.001% by weight to about 1% by weight of a first cationic compound that is amino acid;
about 0.001% by weight to about 1% by weight of a second cationic compound that is organic acid; and
about 1% by weight to about 5% by weight of non-ionic polyhydric alcohol including at least two hydroxyl groups.

2. The slurry composition of claim 1, wherein the amine compound comprises diamine, triamine, tetramine, pentamine, or hexamine.

3. The slurry composition of claim 2, wherein the amine compound comprises a main chain having 1 to 20 carbon atoms, in which two terminals are terminated with amine groups.

4. The slurry composition of claim 3, wherein the main chain of the amine compound has 2 to 20 carbon atoms and at least one nitrogen is included in the main chain.

5. The slurry composition of claim 3, wherein the amine compound comprises at least one selected from the group consisting of methane diamine, ethane-1,2-diamine, propane-1,3-diamine, butane-1,4-diamine, pentane-1,5-diamine, hexane-1,6-diamine, heptane-1,7-diamine, octane-1,8-diamine, diethylene triamine, dipropylene triamine, triethylene tetramine, tripropylene tetramine, tetraethylene pentamine, pentaethylene hexamine, hexaethylene heptamine, bis(hexamethylene)triamine, N-(3-aminopropyl)ethylenediamine, N,N′-bis(3-aminopropyl)ethylenediamine, N,N′-bis(2-aminoethyl)-1,3-propanediamine, N,N,N′-tris(3-aminopropyl)ethylenediamine, N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, N,N,N′N′-tetrakis(2-hydroxypropyl) ethylenediamine, N,N,N′,N′-tetramethylpropanediamine, [symbol] -t-butylethylenediamine, 3,3′-iminobis(propylamine), N-methyl-3,3′-iminobis(propylamine), N,N′-bis(3-aminopropyl)-1,3-propylenediamine, N,N′-bis(3-aminopropyl)-1,4-butylenediamine, N,N′-bis(4-aminobutyl)-1,4-butanediamine, N,N′-bis(2-aminoethyl)-1,4-butanediamine, N,N′-bis(2-aminoethyl)ethylenediamine, bis(3-aminopropyl)amine, bis(4-aminobutyl)amine, bis(5-aminopentyl)amine, N-(6-aminohexyl)-1,6-hexanediamine, hexahydro-1,3,5-triazine, N-methylethylenediamine, N-ethylethylenediamine, N-propylethylenediamine, N-butylethylenediamine, N-methyl-1,3-diaminopropane, N-methyl-1,4-diaminobutane, N-methyl-1,5-diaminopentane, N-methyl-1,6-diaminohexane, N-methyl-1,7-diaminoheptane, N-methyl-1,8-diaminooctane, N-methyl-1,9-diaminononane, N-methyl-1,10-diaminodecane, N-methyl-1,11-diaminoundecane, N-methyl-1,12-diaminododecane, 1,3-bis(aminomethyl)cyclohexane, 1,4-bis(aminomethyl)cyclohexane, piperazine, and derivatives thereof.

6. The slurry composition of claim 1, wherein the non-ionic polyhydric alcohol is a sugar alcohol compound obtained by reducing sugar.

7. The slurry composition of claim 6, wherein the non-ionic polyhydric alcohol comprises at least one selected from the group consisting of maltitol, lactitol, threitol, erythritol, ribitol, xylitol, arabitol, adonitol, sorbitol, talitol, isomalt, mannitol, iditol, allodulcitol, dulcitol, sedoheptitol, and perseitol.

8. The slurry composition of claim 1, wherein the first cationic compound comprises at least one selected from the group consisting of arginine, lysine, histidine, aspartic acid, glutamic acid, asparagine, glutamine, tyrosine, serine, cysteine, threonine, glycine, alanine, β-alanine, proline, tryptophan, methionine, phenylalanine, valine, leucine, and isoleucine.

9. The slurry composition of claim 1, wherein the second cationic compound comprises at least one selected from the group consisting of pimelic acid, malic acid, malonic acid, maleic acid, acetic acid, 2,2-dichloroacetic acid, trifluoroacetic acid, pelargonic acid, valeric acid, enanthic acid, myristic acid, azelaic acid, adipic acid, orotic acid, oxalic acid, succinic acid, mercaptosuccinic acid, alginic acid, tartaric acid, carbonic acid, cinnamic acid, citric acid, lactic acid, lactobionic acid, glutaric acid, 2-oxo-glutaric acid, glucoheptonic acid, gluconic acid, glucuronic acid, glutamic acid, pyroglutamic acid, glycolic acid, formic acid, fumaric acid, palmitic acid, pamoic acid, propionic acid, butyric acid, hydroxybutyric acid, ascorbic acid, aspartic acid, aspartic acid, stearic acid, thiocyanic acid, itaconic acid, tricarballyic acid, pyruvic acid, suberic acid, benzenesulfonic acid, benzoic acid, 4-acetamidobenzoic acid, 4-(4-hydroxyphenyl)benzoic acid, phenylacetic acid, phenylene diacetic acid, diethylmalonic acid, phenylmalonic acid, phenylene dibutyrate, p-phenylene dicarboxylic acid, 4,4′-diphenyl ether carboxylic acid, 1,5-naphthalene dicarboxylic acid, 2,6-naphthalene dicarboxylic acid, 4′-hydroxy-4-biphenylcarboxylic acid, naphthoic acid, 1-hydroxy-2-naphthoic acid, 6-hydroxy-1-naphthoic acid, mandelic acid, picolinic acid, gentisic acid, nicotinic acid, isonicotinic acid, quinolinic acid, anthranilic acid, fusaric acid, capric acid, caproic acid, caprylic acid, dodecylsulfuric acid, camphoric acid, camphor-10-sulfonic acid, ethane-1,2-disulfonic acid, methanesulfonic acid, ethanesulfonic acid, 2-hydroxyethanesulfonic acid, p-toluenesulfonic acid, naphthalene-1,5-disulfonic acid, naphthalene-2-sulfonic acid, phthalic acid, isophthalic acid, salicylic acid, 4-aminosalicylic acid, terephthalic acid, lauric acid, mucic acid, oleic acid, cyclamic acid, galactaric acid, hippuric acid, glycerophosphoric acid, sebacic acid, undecylenic acid, mellitic acid, trimellitic acid, pyromellitic acid, pyromellitic acid anhydride, and pyridinecarboxylic acid.

10. The slurry composition of claim 1, wherein the polishing particles comprise at least one selected from the group consisting of silica, ceria, zirconia, alumina, titania, barium titania, germania, mangania, and magnesia.

11. The slurry composition of claim 10, wherein the polishing particles comprise colloidal ceria.

12. The slurry composition of claim 1, wherein a pH value of the slurry composition ranges from about 2 to about 6.

13. A slurry composition for a chemical mechanical polishing (CMP) process, the slurry composition comprising:
about 0.1% by weight to about 10% by weight of polishing particles;
about 0.001% by weight to about 1% by weight of an amine compound;
about 0.001% by weight to about 1% by weight of a first cationic compound that is amino acid; and
about 1% by weight to about 5% by weight of non-ionic polyhydric alcohol including at least two hydroxyl groups,
wherein a pH value of the slurry composition ranges from about 2 to about 6.

14. The slurry composition of claim 13, wherein the non-ionic polyhydric alcohol is hydrocarbon having 4 to 20 carbon atoms and comprise 4 to 14 hydroxyl groups.

15. The slurry composition of claim 14, wherein the non-ionic polyhydric alcohol has a structure of Formula 1: 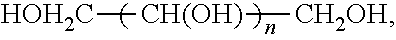
wherein n is an integer ranging from 2 to 12.

16. The slurry composition of claim 13, wherein the non-ionic polyhydric alcohol is a compound having a structure of Formula 2: 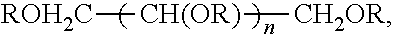
wherein n is an integer ranging 2 to 12, and R is independently hydrogen or a substituent of Formula 3:

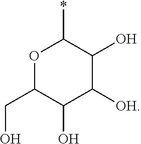 [SMILES: *C1OC(CO)C(O)C(O)C1O]

17. The slurry composition of claim 16, wherein one or two of Rs of the compound of Formula 2 are substituents of Formula 3.

18. A slurry composition for a chemical mechanical polishing (CMP) process, the slurry composition comprising:
about 0.1% by weight to about 10% by weight of polishing particles;
about 0.001% by weight to about 1% by weight of an amine compound;
about 0.001% by weight to about 1% by weight of a first cationic compound that is amino acid; and
about 1% by weight to about 5% by weight of non-ionic polyhydric alcohol,
wherein the non-ionic polyhydric alcohol is hydrocarbon having 4 to 20 carbon atoms and comprises 4 to 14 hydroxyl groups.

19. The slurry composition of claim 18, wherein the non-ionic polyhydric alcohol comprises a C4 moiety in which at least four carbon atoms are connected in a linear chain.

20. The slurry composition of claim 18, further comprising a second cationic compound as organic acid, wherein the second cationic compound is contained in an amount of about 0.001% by weight to about 1% by weight.
